(19) United States
(12) Patent Application Publication
(10) Pub. No.: US 2010/0023282 A1
(43) Pub. Date: Jan. 28, 2010

(54) CHARACTERIZING A COMPUTER SYSTEM USING RADIATING ELECTROMAGNETIC SIGNALS MONITORED THROUGH AN INTERFACE

(75) Inventors: Andrew J. Lewis, Litchfield, NH (US); Kenny C. Gross, San Diego, CA (US); Aleksey M. Urmanov, San Diego, CA (US); Ramakrishna C. Dhanekula, San Diego, CA (US)

Correspondence Address: PVF -- SUN MICROSYSTEMS INC.;C/O PARK, VAUGHAN & FLEMING LLP, 2820 FIFTH STREET, DAVIS, CA, 95618-7759, US

(73) Assignee: SUN MICROSYSTEM, INC., Santa Clara, CA (US)

(21) Appl. No.: 12/177,724

(22) Filed: Jul. 22, 2008

(51) Int. Cl. G01R 35/00

(52) U.S. Cl. 702/57

(57) ABSTRACT

Some embodiments of the present invention provide a system that characterizes a computer system parameter by analyzing a target electromagnetic signal radiating from the computer system. First, the target electromagnetic signal is monitored using a conductor in an interface of the computer system. Then, the target electromagnetic signal is analyzed to characterize the computer system parameter.

### BACKGROUND

1. Field

The present invention generally relates to techniques for monitoring computer systems. More specifically, the present invention relates to a method and an apparatus that characterizes a computer system parameter by analyzing a target electromagnetic signal radiating from the computer system.

2. Related Art

Electromagnetic signals radiated by computer systems can be used to characterize parameters of the computer system. For computer systems that do not have a dedicated built-in antenna to monitor these electromagnetic signals, a hand-held antenna may have to be used. However, variations in the position or orientation that may occur with the used of a hand-held antenna can affect reception of the electromagnetic signal, impacting the sensitivity, accuracy, and repeatability of the characterization of the computer system parameter.

Hence, what is needed is a method and system that characterizes a computer system parameter by analyzing electromagnetic signal radiating from the computer system without the above-described problems.

### SUMMARY

Some embodiments of the present invention provide a system that characterizes a computer system parameter by analyzing a target electromagnetic signal radiating from the computer system. First, the target electromagnetic signal is monitored using a conductor in an interface of the computer system. Then, the target electromagnetic signal is analyzed to characterize the computer system parameter.

In some embodiments, the interface includes a universal serial bus (USB).

In some embodiments, prior to monitoring the target electromagnetic signal, a reference electromagnetic signal radiating from the computer system is monitored and a reference electromagnetic-signal fingerprint is generated from the reference electromagnetic signal. Then, a pattern-recognition model is built based on the reference electromagnetic-signal fingerprint.

In some embodiments, the pattern-recognition model includes a nonlinear, nonparametric regression model.

In some embodiments, analyzing the target electromagnetic signal includes generating a target electromagnetic-signal fingerprint from the target electromagnetic signal, feeding the target electromagnetic-signal fingerprint into the pattern-recognition model, producing an estimated electromagnetic-signal fingerprint using the pattern-recognition model, and comparing the target electromagnetic-signal fingerprint to the estimated electromagnetic fingerprint to characterize the computer system parameter.

In some embodiments, generating the reference electromagnetic-signal fingerprint includes generating a frequency-domain representation of the reference electromagnetic signal, selecting a set of frequencies from the frequency-domain representation of the reference electromagnetic signal, and forming the reference electromagnetic-signal fingerprint using the set of frequencies.

In some embodiments, selecting the set of frequencies includes dividing the frequency-domain representation of the reference electromagnetic signal into a plurality of frequencies, and constructing a reference electromagnetic-signal amplitude-time series for each of the plurality of frequencies based on the reference electromagnetic signal collected over a predetermined time period. The cross-correlations between pairs of reference electromagnetic-signal amplitude-time series associated with pairs of the plurality of frequencies is then computed, and an average correlation coefficient for each of the plurality of frequencies is also computed. Then the set of frequencies is selected based on the average correlation coefficients

In some embodiments, building the pattern-recognition model based on the reference electromagnetic-signal fingerprint includes training the pattern-recognition model using the reference electromagnetic-signal amplitude-time series associated with the set of frequencies as inputs to the pattern-recognition model.

In some embodiments, generating the target electromagnetic-signal fingerprint includes transforming the target electromagnetic signal to a frequency-domain representation and for each frequency in the set of frequencies, generating a target electromagnetic-signal amplitude-time series based on the frequency-domain representation of the target electromagnetic signal collected over time. Then, the target electromagnetic-signal fingerprint is formed using the target electromagnetic-signal amplitude-time series associated with the set of frequencies.

In some embodiments, comparing the target electromagnetic-signal fingerprint to the estimated electromagnetic fingerprint includes, for each frequency in the set of frequencies, computing a residual signal between a corresponding monitored electromagnetic-signal amplitude-time series in the target electromagnetic-signal fingerprint and a corresponding estimated electromagnetic-signal amplitude-time series in the estimated electromagnetic-signal fingerprint, and detecting anomalies in the residual signal by using sequential detection, wherein the anomalies indicate a deviation of the monitored electromagnetic-signal amplitude-time series from the estimated electromagnetic-signal amplitude-time series.

In some embodiments, the sequential detection includes a sequential probability ratio test (SPRT).

### BRIEF DESCRIPTION OF THE FIGURES

FIG. 1 illustrates a system that characterizes a computer system parameter by analyzing a target electromagnetic signal radiating from the computer system in accordance with some embodiments of the present invention.

FIG. 2 presents a flowchart illustrating the process of building a pattern recognition model in accordance with some embodiments of the present invention.

FIG. 3 presents a flowchart illustrating the process of generating the reference electromagnetic-signal fingerprint from the reference electromagnetic signal in accordance with some embodiments of the present invention.

FIG. 4 presents a flowchart illustrating the process of selecting the subset of frequencies based on the correlations between the set of electromagnetic-signal amplitude-time series in accordance with some embodiments of the present invention.

FIG. 5 presents a flowchart illustrating the process of computing mean and variance of residuals for the model estimates in accordance with some embodiments of the present invention.

FIGS. 6A and 6B present flowcharts illustrating the process of monitoring an electromagnetic signal to characterize a computer system parameter by analyzing a target electromagnetic signal radiating from the computer system and monitored by a conductor in an interface in accordance with some embodiments of the present invention.

### DETAILED DESCRIPTION

The following description is presented to enable any person skilled in the art to make and use the disclosed embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present description. Thus, the present description is not intended to be limited to the embodiments shown, but is to be accorded the widest scope consistent with the principles and features disclosed herein.

The data structures and code described in this detailed description are typically stored on a computer-readable storage medium, which may be any device or medium that can store code and/or data for use by a computer system. This includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

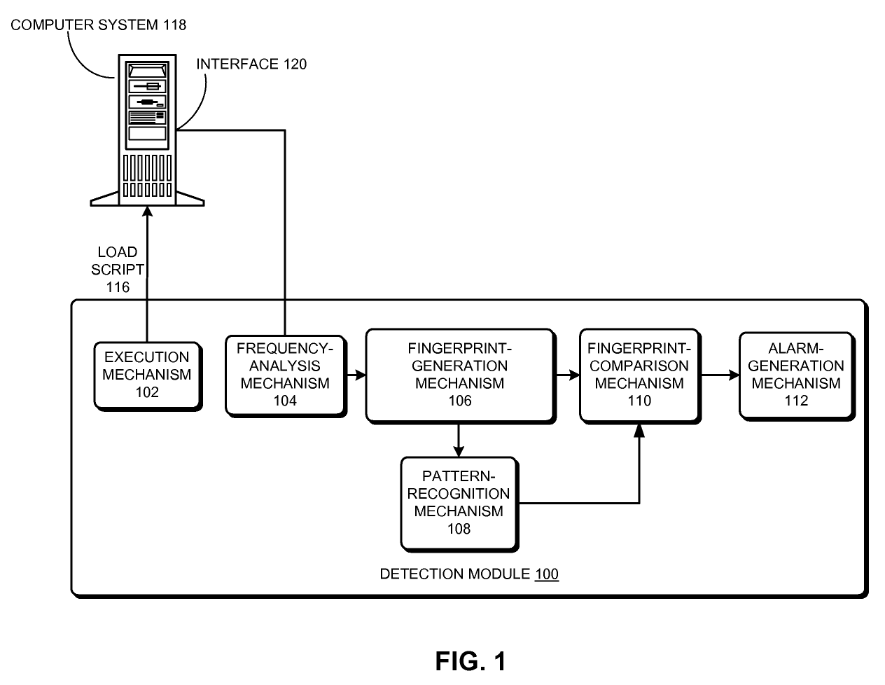

FIG. 1 illustrates a system that characterizes a computer system parameter by analyzing a target electromagnetic signal radiating from the computer system in accordance with some embodiments of the present invention. As illustrated in FIG. 1, detection module 100 includes: execution mechanism 102, frequency-analysis mechanism 104, fingerprint-generation mechanism 106, pattern-recognition mechanism 108, fingerprint-comparison mechanism 110, and alarm-generation mechanism 112. Computer system 118 includes interface 120.

Execution mechanism 102 causes load script 116 to run on computer system 118. Frequency-analysis mechanism 104 is coupled to interface and fingerprint-generation mechanism 106. Fingerprint-generation mechanism 106 is coupled to pattern-recognition mechanism 108 and fingerprint-comparison mechanism 110. Pattern-recognition mechanism 108 is coupled to fingerprint-comparison mechanism 110, and fingerprint-comparison mechanism 110 is coupled to alarm-generation mechanism 112.

Frequency-analysis mechanism 104, fingerprint-generation mechanism 106, pattern-recognition mechanism 108, fingerprint-comparison mechanism 110, and alarm-generation mechanism 112 can each be implemented in any combination of hardware and software. In some embodiments one or more of these mechanisms operates on computer system 118. In some embodiments, one or more of these mechanisms operates on one or more service processors. In some embodiments, one or more of these mechanisms is located inside computer system 118. In some embodiments, one or more of these mechanisms operates on a separate computer system. In some embodiments, one or more of these mechanisms are located in a small form factor package that plugs into and is powered by interface 120. In some of these embodiments, alarm-generation mechanism 112 includes a communication mechanism to communicate results generated by detection module 100. The communication mechanism can include but is not limited to a signal light, or any wired or wireless communication mechanism known in the art.

Computer system 118 can include but is not limited to a server, a server blade, a datacenter server, an enterprise computer, a field-replaceable unit that includes a processor, or any other computation system that includes one or more processors and one or more cores in each processor.

Interface 120 is any interface for computer system 118 that includes one or more electrical conductors and can include but is not limited to a universal serial bus (USB), Ethernet port, serial port, printer port, or any other interface now known or later developed. In some embodiments, electromagnetic signals radiated by computer system 118 are monitored by a conductor in interface 118 connected to a ground line, a signal line, a power line, a neutral line, or any other conductor in computer system 118 that is coupled to a conductor in interface 118 and monitors an electromagnetic signal radiated by computer system 118. In some embodiments, frequency-analysis mechanism 104 is coupled to conductors in two or more interfaces in computer system 118. In some of these embodiments the sum of the electromagnetic signals monitored from the conductor in each interface is used in frequency analysis mechanism 106 and in other embodiments a differential signal representing a difference in the electromagnetic signals monitored from the conductor in each interface is used in frequency analysis mechanism 106. In some embodiments, each signal monitored by a conductor in each interface in separately input into frequency-analysis mechanism 104 and separately undergoes a computer-system-parameter-detection process in detection mechanism 100.

The electromagnetic signals radiated by computer system 118 and monitored by a conductor in interface 120 can be used to characterize any parameter of a computer system including but not limited to any one or more of the following parameters for one or more components in the computer system or the computer system as a whole: model or manufacturer; the presence and length of metal whiskers, a physical variable, a fault, a prognostic variable, or any other parameter that affects an electromagnetic signal radiated from a computer system include but not limited to those discussed in the following: U.S. patent application entitled “Using EMI Signals to Facilitate Proactive Fault Monitoring in Computer Systems,” by Kenny C. Gross, Aleksey M. Urmanov, Ramakrishna C. Dhanekula and Steven F. Zwinger, Attorney Docket No. SUN07-0149, application Ser. No. 11/787,003, filed 12 Apr. 2007, which is hereby fully incorporated by reference; U.S. patent application entitled “Method and Apparatus for Generating an EMI Fingerprint for a Computer System,” by Kenny C. Gross, Aleksey M. Urmanov, and Ramakrishna C. Dhanekula, Attorney Docket No. SUN07-0214, application Ser. No. 11/787,027, filed 12 Apr. 2007, which is hereby fully incorporated by reference; U.S. patent application entitled “Accurately Inferring Physical Variable Values Associated with Operation of a Computer System,” by Ramakrishna C. Dhanekula, Kenny C. Gross, and Aleksey M. Urmanov, Attorney Docket No. SUN07-0504, application Ser. No. 12/001,369, filed 10 Dec. 2007, which is hereby fully incorporated by reference; U.S. patent application entitled “Proactive Detection of Metal Whiskers in Computer Systems,” by Ramakrishna C. Dhanekula, Kenny C. Gross, and David K. McElfresh, Attorney Docket No. SUN07-0762, application Ser. No. 11/985,288, filed 13 Nov. 2007, which is hereby fully incorporated by reference; U.S. patent application entitled “Detecting Counterfeit Electronic Components Using EMI Telemetric Fingerprints,” by Kenny C. Gross, Ramakrishna C. Dhanekula, and Andrew J. Lewis, Attorney Docket No. SUN08-0037, application Ser. No. 11/974,788, filed 16 Oct. 2007, which is hereby fully incorporated by reference; and U.S. patent application entitled “Determining a Total Length for Conductive Whiskers in Computer Systems,” by David K. McElfresh, Kenny C. Gross, and Ramakrishna C. Dhanekula, Attorney Docket No. SUN08-0122, application Ser. No. 12/126,612, filed 23 May 2008, which is hereby fully incorporated by reference.

In some embodiments of the present invention, execution mechanism 102 causes load script 116 to be executed by computer system 118 during the computer-system-parameter-detection process. Note that the computer-system-parameter-detection process can be performed in parallel with normal computer system operation. In some embodiments of the present invention, execution mechanism 102 is only used during the training phase of the computer-system-parameter-detection process. Hence, execution mechanism 102 is idle during the monitoring phase of the computer-system-parameter-detection process. In other embodiments, execution mechanism 102 causes load script 116 to be executed by computer system 118 during the training phase. Then, during the computer-system-parameter-detection process, normal computer system operation is interrupted and execution mechanism 102 causes load script 116 to be executed by computer system 118. In some embodiments of the present invention, load script 116 is stored on computer system 118.

In some embodiments of the present invention, load script 116 can include: a sequence of instructions that produces a load profile that oscillates between specified processor utilization percentages for a processor in computer system 118; a sequence of instructions that produces a customized load profile; and/or a sequence of instructions that executes predetermined instructions causing operation of one or more devices or processes in computer system 118. In some embodiments of the present invention, load script 116 is a dynamic load script which changes the load on the processor as a function of time.

In some embodiments of the present invention, during the computer-system-parameter-detection process, the electromagnetic signal generated in computer system 118 is monitored by a conductor in interface 120. It is noted that the electromagnetic signal can be comprised of a set of one or more electromagnetic signals.

The target electromagnetic signal monitored by a conductor in interface 120 is received by frequency-analysis mechanism 104, which then transforms the collected electromagnetic signal time-series to the frequency-domain. In some embodiments of the present invention, the received target electromagnetic signal is amplified prior to being transformed into the frequency domain. In some embodiments of the present invention, frequency-analysis mechanism 104 can include a spectrum analyzer.

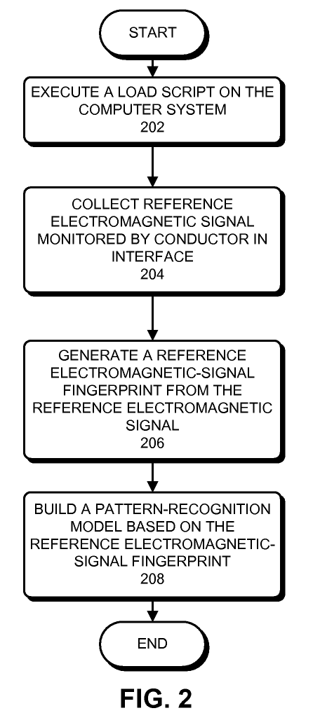

Frequency-analysis mechanism 104 is coupled to fingerprint-generation mechanism 106. In some embodiments of the present invention, fingerprint-generation mechanism 106 is configured to generate an electromagnetic-signal fingerprint based on the frequency-domain representation of the electromagnetic signal. This process is described in more detail below in conjunction with FIG. 2.

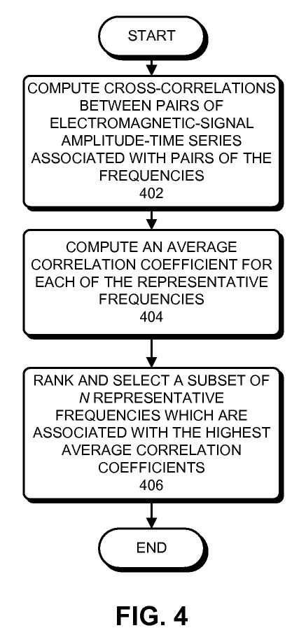

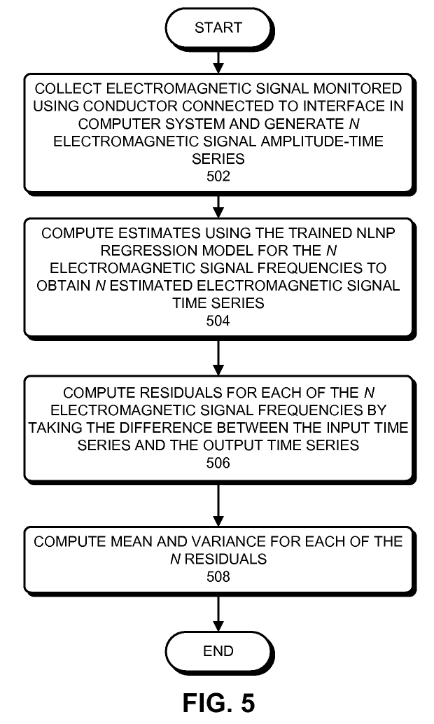

As illustrated in FIG. 1, the output of fingerprint-generation mechanism 106 is coupled to the inputs of both pattern-recognition module 108 and fingerprint-comparison mechanism 110. In some embodiments of the present invention, pattern-recognition module 108 performs at least two functions. First, pattern-recognition module 108 builds pattern-recognition model for estimate the electromagnetic-signal fingerprint associated with the electromagnetic signal monitored by a conductor in interface 120. Second, pattern-recognition module 108 can use the pattern-recognition model to compute estimates of the electromagnetic-signal fingerprint associated with the electromagnetic signal monitor by the conductor in interface 120. This operation of pattern-recognition module 108 is described in more detail below in conjunction with FIGS. 4 and 5.

Fingerprint-comparison mechanism 110 compares the electromagnetic-signal fingerprint generated by fingerprint-generation mechanism 106 to an estimated electromagnetic-signal fingerprint computed by the pattern-recognition model. The comparison operation performed by fingerprint-comparison mechanism 110 is described in more detail below in conjunction with FIG. 5. Alarm-generation mechanism 112 is configured to generate an alarm based on the comparison results from fingerprint-comparison mechanism 110. In some embodiments, information related to the generated alarms is used to characterize information related to the parameter of computer system 118. The information related to the parameter of the computer system can include but is not limited to any of the parameters discussed in the U.S. patent applications referenced above.

In some embodiments, detection module 100 also includes a performance-parameter-monitoring mechanism that monitors performance parameters of computer system 118. In some embodiments, the performance-parameter monitor includes an apparatus for monitoring and recording computer system performance parameters as set forth in U.S. Pat. No. 7,020,802, entitled “Method and Apparatus for Monitoring and Recording Computer System Performance Parameters,” by Kenny C. Gross and Larry G. Votta, Jr., issued on 28 Mar. 2006, which is hereby fully incorporated by reference. The performance-parameter-monitoring mechanism monitors the performance parameters of computer system 118 and sends information related to the monitored performance parameters to frequency-analysis mechanism 104. In these embodiments, information related to the monitored performance parameters are built into the pattern-recognition model, the generated fingerprints and the estimated fingerprints resulting from the electromagnetic signal monitored by the conductor in interface 120.

In some embodiments of the present invention, prior to characterizing the parameter of computer system 118, detection module 100 build a pattern-recognition model when the parameter of computer system 118 is in a known state. For example, if the parameter being characterized is the authenticity of components in computer system 118, then the pattern-recognition model is built when the components in computer system 118 have been verified to be authentic. FIG. 2 presents a flowchart illustrating the process of building a pattern-recognition model in accordance with some embodiments of the present invention.

During operation, the detection module executes a load script on computer system, wherein the load script includes a specified sequence of operations (step 202). In some embodiments of the present invention, the load script is a dynamic load script which changes the load on a processor in the computer system as a function of time. While executing the load script, the detection module collects a reference electromagnetic signal time-series using the electromagnetic signal monitored by the conductor in interface 120 (step 204). In some embodiments of the present invention, the reference electromagnetic signal can be collected when the computer system is first deployed in the field and the parameter of the computer system is in a known state. In another embodiment, the reference electromagnetic signal can be collected when the parameter of the computer system is determined to be in a predetermined state.

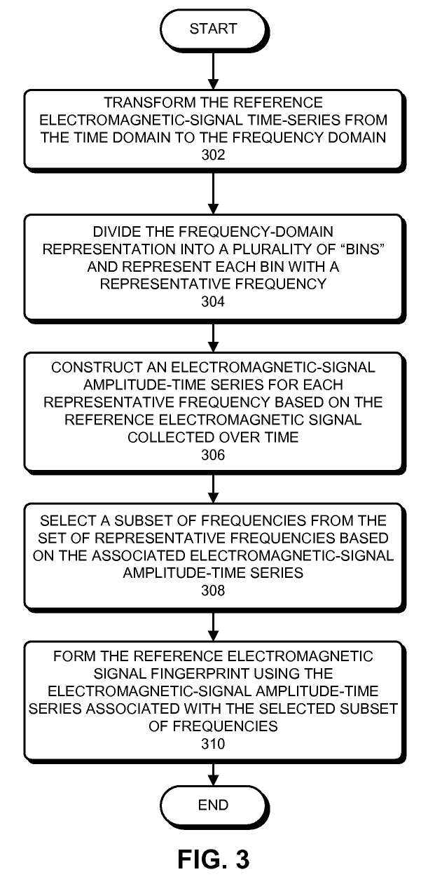

Next, the system generates a reference electromagnetic-signal fingerprint from the reference electromagnetic signal (step 206). We describe the process of generating the reference electromagnetic-signal fingerprint below in conjunction with FIG. 3. The system next builds the pattern-recognition model based on the reference electromagnetic-signal fingerprint (step 208). Note that step 208 can be performed by pattern-recognition mechanism 108 in FIG. 1. We describe step 208 further below after we provide more details of generating the reference electromagnetic-signal fingerprint.

FIG. 3 presents a flowchart illustrating the process of generating the reference electromagnetic-signal fingerprint from the reference electromagnetic signal in accordance with some embodiments of the present invention.

During operation, the system starts by transforming the electromagnetic-signal time-series from the time domain to the frequency domain (step 302). In some embodiments of the present invention, transforming the electromagnetic-signal time-series from the time domain to the frequency domain involves using a fast Fourier transform (FFT). In other embodiments, other transform functions can be used, including, but not limited to, a Laplace transform, a discrete Fourier transform, a Z-transform, and any other transform technique now known or later developed.

The system then divides the frequency range associated with the frequency-domain representation of the reference electromagnetic signal into a plurality of “bins,” and represents each discrete bin with a representative frequency (step 304). For example, one can divide the frequency range into about 600 bins. In some embodiments, these frequency bins and the associated frequencies are equally spaced.

Next, for each of the plurality of representative frequencies, the system constructs an electromagnetic-signal amplitude-time series based on the reference electromagnetic-signal time series collected over a predetermined time period (step 306). In some embodiments, to generate the time series for each frequency, the electromagnetic signal is sampled at predetermined time intervals, for example once every second or every minute. Next, each of the sampled electromagnetic signal intervals is transformed into the frequency domain, and an electromagnetic-signal amplitude-time pair is subsequently extracted for each of the representative frequencies at each time interval. In this way, the system generates a large number of separate electromagnetic-signal amplitude-time series for the plurality of frequencies.

The system next selects a subset of frequencies from the plurality of frequencies based on the associated electromagnetic-signal amplitude-time series (step 308). It is noted that in some embodiments, a subset of frequencies is not selected and the system uses all of the available frequencies. In some embodiments, selecting the subset of frequencies optimizes detection sensitivity while minimizing computation costs.

FIG. 4 presents a flowchart illustrating the process of selecting the subset of frequencies based on the correlations between the set of electromagnetic-signal amplitude-time series in accordance with some embodiments of the present invention. During operation, the system computes cross-correlations between pairs of electromagnetic-signal amplitude-time series associated with pairs of the representative frequencies (step 402). Next, the system computes an average correlation coefficient for each of the plurality of representative frequencies (step 404). The system then ranks and selects a subset of N representative frequencies which are associated with the highest average correlation coefficients (step 406). Note that the electromagnetic-signal amplitude-time series associated with these N frequencies are the most highly correlated with other amplitude-time series. In some embodiments of the present invention, N is typically less than or equal to 20.

Referring back to FIG. 3, when the subset of frequencies has been selected, the system forms the reference electromagnetic-signal fingerprint using the electromagnetic-signal amplitude-time series associated with the selected frequencies (step 310).

Referring back to step 208 in FIG. 2, note that when the reference electromagnetic-signal fingerprint is generated, the system uses the set of N electromagnetic-signal amplitude-time series associated with the selected frequencies as training data to train the pattern-recognition model. In some embodiments of the present invention, the pattern-recognition model is a non-linear, non-parametric (NLNP) regression model. In some embodiments, the NLNP regression technique includes a multivariate state estimation technique (MSET). The term “MSET” as used in this specification refers to a class of pattern-recognition algorithms. For example, see [Gribok] “Use of Kernel Based Techniques for Sensor Validation in Nuclear Power Plants,” by Andrei V. Gribok, J. Wesley Hines, and Robert E. Uhrig, The Third American Nuclear Society International Topical Meeting on Nuclear Plant Instrumentation and Control and Human-Machine Interface Technologies, Washington D.C., Nov. 13-17, 2000. This paper outlines several different pattern recognition approaches. Hence, the term “MSET” as used in this specification can refer to (among other things) any technique outlined in [Gribok], including Ordinary Least Squares (OLS), Support Vector Machines (SVM), Artificial Neural Networks (ANNs), MSET, or Regularized MSET (RMSET).

During this model training process, an NLNP regression model receives the set of electromagnetic-signal amplitude-time series (i.e., the reference electromagnetic-signal fingerprint) as inputs (i.e., training data), and learns the patterns of interaction between the set of N electromagnetic-signal amplitude-time series. Consequently, when the training is complete, the NLNP regression model is configured and ready to perform model estimates for the same set of N electromagnetic-signal amplitude-time series.

In some embodiments of the present invention, when the NLNP regression model is built, it is subsequently used to compute mean and variance of residuals associated with the model estimates. Note that these mean and variance values will be used during the monitoring process as described below. Specifically, FIG. 5 presents a flowchart illustrating the process of computing mean and variance of residuals for the model estimates in accordance with some embodiments of the present invention.

During operation, the system receives an electromagnetic signal monitored using a conductor in an interface in the computer system and generates the same set of N electromagnetic-signal amplitude-time series in a process as described above (step 502). The system then computes estimates using the trained NLNP regression model for the set of N electromagnetic signal frequencies (step 504). Specifically, the NLNP regression model receives the set of N electromagnetic-signal amplitude-time series as inputs and produces a corresponding set of N estimated electromagnetic-signal amplitude-time series as outputs. Next, the system computes the residuals for each of the N electromagnetic signal frequencies by taking the difference between the corresponding input time series and the output time series (step 506). Hence, the system obtains N residuals. The system then computes mean and variance for each of the N residuals (step 508).

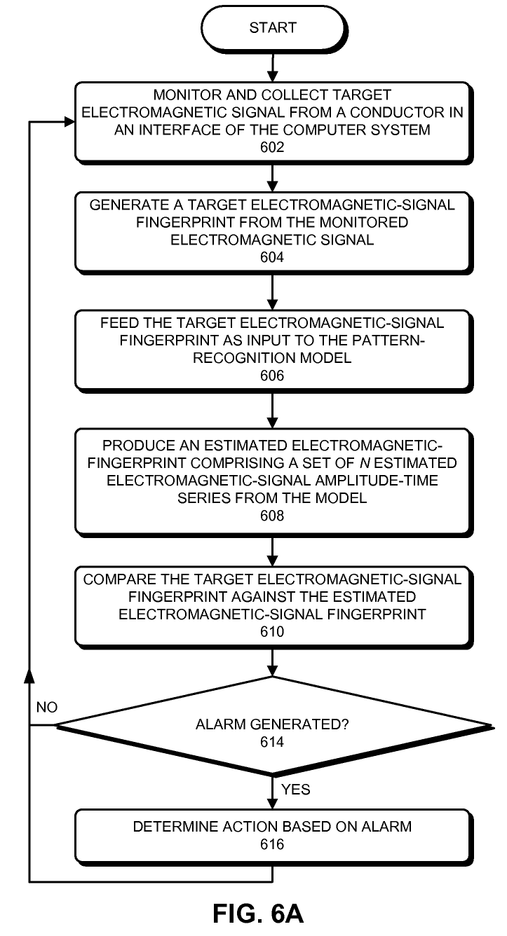

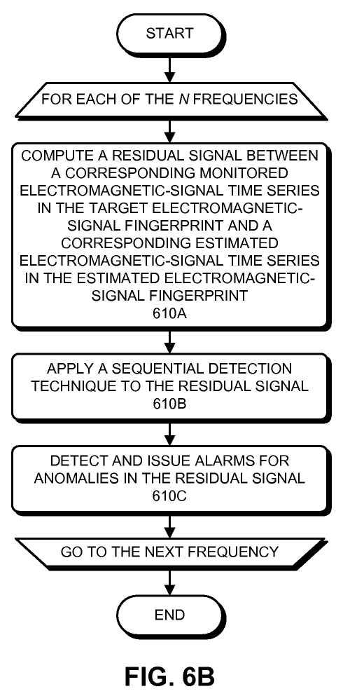

FIGS. 6A and 6B present flowcharts illustrating the process of monitoring an electromagnetic signal to characterize a computer system parameter by analyzing a target electromagnetic signal radiating from the computer system and monitored by a conductor in an interface in a computer system in accordance with some embodiments of the present invention. During a monitoring operation, the system monitors and collects an electromagnetic signal from a conductor in an interface in the computer system. In some embodiments of the present invention, the computer system is performing routine operations during the monitoring process; hence, the computer system may be executing any workload during this process. In other embodiments, the computer system executes a load script during the monitoring process.

The system then generates a target electromagnetic-signal fingerprint from the monitored electromagnetic signal (step 604). Note that the target electromagnetic-signal fingerprint can be generated from the electromagnetic signal in a similar manner to generating the reference electromagnetic-signal fingerprint as described in conjunction with FIG. 3. In some embodiments of the present invention, the system generates the target electromagnetic signal fingerprint by: (1) transforming the monitored electromagnetic-signal time-series from the time-domain to the frequency-domain; (2) for each of the set of N frequencies in the reference electromagnetic-signal fingerprint, generating a monitored electromagnetic-signal amplitude-time series based on the frequency-domain representation of the monitored electromagnetic-signal collected over time; and (3) forming the target electromagnetic-signal fingerprint using the set of N monitored electromagnetic-signal amplitude-time series associated with the selected N frequencies. In some embodiments of the present invention, the target electromagnetic-signal fingerprint comprises all the N frequencies as the reference electromagnetic-signal fingerprint. In a further embodiment, the target electromagnetic-signal fingerprint comprises a subset of the N frequencies in the reference electromagnetic-signal fingerprint.

Next, the system feeds the target electromagnetic-signal fingerprint as input to the pattern-recognition model which has been trained using the reference electromagnetic-signal fingerprint (step 606), and subsequently produces an estimated electromagnetic-signal fingerprint as output (step 608). In some embodiments of the present invention, the estimated electromagnetic-signal fingerprint comprises a set of N estimated electromagnetic-signal amplitude-time series corresponding to the set of N monitored electromagnetic-signal amplitude-time series in the target electromagnetic-signal fingerprint.

The system then compares the target electromagnetic-signal fingerprint against the estimated electromagnetic-signal fingerprint (step 610). This step is shown in more detail in FIG. 6B. Specifically, for each of the selected N frequencies, the system computes a residual signal between a corresponding monitored electromagnetic-signal amplitude-time series in the target electromagnetic-signal fingerprint and a corresponding estimated electromagnetic-signal amplitude-time series in the estimated electromagnetic-signal fingerprint (step 610A). The system then applies a sequential detection technique to the residual signal (step 610B). In some embodiments of the present invention, the sequential detection technique is a Sequential Probability Ratio Test (SPRT). In some embodiments of the present invention, the SPRT uses the mean and variance computed for the corresponding residual signal during the model training process to detect anomalies in the residual signal, wherein the anomalies indicate a deviation of the monitored electromagnetic-signal amplitude-time series from the estimated electromagnetic-signal amplitude-time series. Note that when such anomalies are detected in the residual signal, SPRT alarms are subsequently issued (step 810C).

Referring back to FIG. 6A, the system next determines if anomalies are detected in at least one of the N monitored electromagnetic-signal amplitude-time series, for example, based on the SPRT alarms. If an alarm is not generated (step 614), the process returns to step 602. If an alarm is generated then it is determined what action should be taken based on the alarm (step 616).

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

What is claimed is:

1. A method for characterizing a computer system parameter by analyzing a target electromagnetic signal radiating from the computer system, the method comprising:
monitoring the target electromagnetic signal using a conductor in an interface of the computer system; and
analyzing the target electromagnetic signal to characterize the computer system parameter.

2. The method of claim 1, wherein the interface includes a universal serial bus (USB).

3. The method of claim 1, wherein prior to monitoring the target electromagnetic signal, the method further comprises:
monitoring a reference electromagnetic signal radiating from the computer system;
generating a reference electromagnetic-signal fingerprint from the reference electromagnetic signal; and
building a pattern-recognition model based on the reference electromagnetic-signal fingerprint.

4. The method of claim 3, wherein the pattern-recognition model includes a nonlinear, nonparametric regression model.

5. The method of claim 3, wherein analyzing the target electromagnetic signal includes:
generating a target electromagnetic-signal fingerprint from the target electromagnetic signal;
feeding the target electromagnetic-signal fingerprint into the pattern-recognition model;
producing an estimated electromagnetic-signal fingerprint using the pattern-recognition model; and
comparing the target electromagnetic-signal fingerprint to the estimated electromagnetic fingerprint to characterize the computer system parameter.

6. The method of claim 5, wherein generating the reference electromagnetic-signal fingerprint includes:
generating a frequency-domain representation of the reference electromagnetic signal;
selecting a set of frequencies from the frequency-domain representation of the reference electromagnetic signal; and
forming the reference electromagnetic-signal fingerprint using the set of frequencies.

7. The method of claim 6, wherein selecting the set of frequencies includes:
dividing the frequency-domain representation of the reference electromagnetic signal into a plurality of frequencies;
constructing a reference electromagnetic-signal amplitude-time series for each of the plurality of frequencies based on the reference electromagnetic signal collected over a predetermined time period;
computing cross-correlations between pairs of reference electromagnetic-signal amplitude-time series associated with pairs of the plurality of frequencies;
computing an average correlation coefficient for each of the plurality of frequencies; and
selecting the set of frequencies based on the average correlation coefficients.

8. The method of claim 7, wherein building the pattern-recognition model based on the reference electromagnetic-signal fingerprint includes:
training the pattern-recognition model using the reference electromagnetic-signal amplitude-time series associated with the set of frequencies as inputs to the pattern-recognition model.

9. The method of claim 6, wherein generating the target electromagnetic-signal fingerprint includes:
transforming the target electromagnetic signal to a frequency-domain representation;
for each frequency in the set of frequencies, generating a target electromagnetic-signal amplitude-time series based on the frequency-domain representation of the target electromagnetic signal collected over time; and
forming the target electromagnetic-signal fingerprint using the target electromagnetic-signal amplitude-time series associated with the set of frequencies.

10. The method of claim 9, wherein comparing the target electromagnetic-signal fingerprint to the estimated electromagnetic fingerprint includes:
for each frequency in the set of frequencies,
computing a residual signal between a corresponding monitored electromagnetic-signal amplitude-time series in the target electromagnetic-signal fingerprint and a corresponding estimated electromagnetic-signal amplitude-time series in the estimated electromagnetic-signal fingerprint; and
detecting anomalies in the residual signal by using sequential detection, wherein the anomalies indicate a deviation of the monitored electromagnetic-signal amplitude-time series from the estimated electromagnetic-signal amplitude-time series.

11. The method of claim 10, wherein the sequential detection includes a sequential probability ratio test (SPRT).

12. A computer-readable storage medium storing instructions that when executed by a computer cause the computer to perform a method for characterizing a computer system parameter by analyzing a target electromagnetic signal radiating from the computer system, the method comprising:
monitoring the target electromagnetic signal using a conductor in an interface of the computer system; and
analyzing the target electromagnetic signal to characterize the computer system parameter.

13. The computer-readable storage medium of claim 12, wherein the interface includes a universal serial bus (USB).

14. The computer-readable storage medium of claim 12, wherein prior to monitoring the target electromagnetic signal, the method further comprises:
monitoring a reference electromagnetic signal radiating from the computer system;
generating a reference electromagnetic-signal fingerprint from the reference electromagnetic signal; and
building a pattern-recognition model based on the reference electromagnetic-signal fingerprint, wherein the pattern-recognition model includes a nonlinear, nonparametric regression model.

15. The computer-readable storage medium of claim 14, wherein analyzing the target electromagnetic signal includes:
generating a target electromagnetic-signal fingerprint from the target electromagnetic signal;
feeding the target electromagnetic-signal fingerprint into the pattern-recognition model;
producing an estimated electromagnetic-signal fingerprint using the pattern-recognition model; and
comparing the target electromagnetic-signal fingerprint to the estimated electromagnetic fingerprint to characterize the computer system parameter.

16. The computer-readable storage medium of claim 15, wherein generating the reference electromagnetic-signal fingerprint includes:
generating a frequency-domain representation of the reference electromagnetic signal;
selecting a set of frequencies from the frequency-domain representation of the reference electromagnetic signal; and
forming the reference electromagnetic-signal fingerprint using the set of frequencies.

17. The computer-readable storage medium of claim 16, wherein selecting the set of frequencies includes:
dividing the frequency-domain representation of the reference electromagnetic signal into a plurality of frequencies;
constructing a reference electromagnetic-signal amplitude-time series for each of the plurality of frequencies based on the reference electromagnetic signal collected over a predetermined time period, wherein building the pattern-recognition model based on the reference electromagnetic-signal fingerprint includes training the pattern-recognition model using the reference electromagnetic-signal amplitude-time series associated with the set of frequencies as inputs to the pattern-recognition model;
computing cross-correlations between pairs of reference electromagnetic-signal amplitude-time series associated with pairs of the plurality of frequencies;
computing an average correlation coefficient for each of the plurality of frequencies; and
selecting the set of frequencies based on the average correlation coefficients.

18. The computer-readable storage medium of claim 16, wherein generating the target electromagnetic-signal fingerprint includes:
transforming the target electromagnetic signal to a frequency-domain representation;
for each frequency in the set of frequencies, generating a target electromagnetic-signal amplitude-time series based on the frequency-domain representation of the target electromagnetic signal collected over time; and
forming the target electromagnetic-signal fingerprint using the target electromagnetic-signal amplitude-time series associated with the set of frequencies.

19. The computer-readable storage medium of claim 18, wherein comparing the target electromagnetic-signal fingerprint to the estimated electromagnetic fingerprint includes:
for each frequency in the set of frequencies,
computing a residual signal between a corresponding monitored electromagnetic-signal amplitude-time series in the target electromagnetic-signal fingerprint and a corresponding estimated electromagnetic-signal amplitude-time series in the estimated electromagnetic-signal fingerprint; and
detecting anomalies in the residual signal by using sequential detection, wherein the anomalies indicate a deviation of the monitored electromagnetic-signal amplitude-time series from the estimated electromagnetic-signal amplitude-time series.

20. An apparatus for characterizing a computer system parameter by analyzing a target electromagnetic signal radiating from the computer system, comprising:
a monitoring mechanism configured to monitor the target electromagnetic signal using a conductor in an universal serial bus (USB) interface of the computer system; and
an analyzing mechanism configured to analyze the target electromagnetic signal to characterize the computer system parameter.
